(19) United States
(12) Patent Application Publication
(10) Pub. No.: US 2026/0202565 A1
(43) Pub. Date: Jul. 16, 2026

(54) CALCULATION METHOD FOR MOHO DEPTH OF EXTRATERRESTRIAL CELESTIAL BODY AND RELATED APPARATUS

(71) Applicant: INSTITUTE OF GEOLOGY AND GEOPHYSICS, CAS, BEIJING (CN)

(72) Inventors: WEIJIA SUN, BEIJING (CN); KEXU SHI, BEIJING (CN); QINGYA TANG, BEIJING (CN); YONGXIN PAN, BEIJING (CN)

(21) Appl. No.: 19/390,017

(22) Filed: Nov. 14, 2025

(30) Foreign Application Priority Data
Nov. 15, 2024 (CN) 202411642336.8

(51) Int. Cl. G01V 1/30; G01V 1/28

(52) U.S. Cl. CPC G01V 1/301; G01V 1/282; G01V 1/303

(57) ABSTRACT

The present application provides a calculation method for a Mohorovičić discontinuity (Moho) depth of an extraterrestrial celestial body and a related apparatus. The method includes: obtaining a seismic event with location information from a target extraterrestrial celestial body, and picking up observed travel time differences T_{obs} of a plurality of seismic phases of seismic body waves relative to a first-arriving P-wave; establishing a plurality of seismological structural models, and calculating a theoretical travel time and a theoretical P-wave first-arrival time for each seismic phase to obtain a theoretical travel time difference T_{cal} of the seismic phase relative to the first-arriving P-wave; and calculating a travel time residual Tᵣₑₛ of each seismological structural model based on the theoretical travel time difference T_{cal} and the observed travel time differences T_{obs} so as to determine an average Moho depth of an event-station great circle path of the target extraterrestrial celestial body.

### CROSS REFERENCE TO RELATED APPLICATION

This patent application claims the benefit and priority of Chinese Patent Application No. 2024116423368, filed with the China National Intellectual Property Administration on Nov. 15, 2024, the disclosure of which is incorporated by reference herein in its entirety as part of the present application.

### TECHNICAL FIELD

The present application relates to the technical field of deep space exploration data processing, and in particular, to a calculation method for a Mohorovičić discontinuity (Moho) depth of an extraterrestrial celestial body and a related apparatus.

### BACKGROUND

Deep space exploration represents one of the most cutting-edge and dynamic frontiers of technological development. In lunar deep space exploration missions, it is common practice to deploy a seismometer on the Moon to investigate the internal structure of the Moon. Due to technical restrictions such as limited space, restricted payload mass and volume of a probe, as well as economic considerations, only one seismometer can be deployed for one deep space exploration mission.

The Mohorovičić discontinuity (Moho) refers to the interface between the crust and the mantle. Obtaining a Moho depth is a key scientific objective of a deep space exploration mission. This is mainly because the Moho depth contains critical information regarding the formation and evolution of the Moon, Mars, and other extraterrestrial celestial bodies. By obtaining Moho depths, the interactions between the crusts and mantles can be further understood, thereby revealing the formation and evolutionary history of these extraterrestrial celestial bodies.

Currently, the primary method for detecting a Moho depth is a receiver function method. By this method, the Moho depth beneath a seismometer can be effectively inferred by analyzing the reflection and refraction characteristics of seismic waves at the crust-mantle boundary. However, the receiver function method has a significant limitation, i.e., it can only provide the Moho depth information at the location where the seismometer is deployed, and cannot obtain the Moho depth distribution over a larger area. Given the potential complex geological structures of extraterrestrial celestial bodies such as the Moon and Mars, this limitation hinders a comprehensive understanding of their internal structures, thereby constraining in-depth insight into the formation processes and evolutionary mechanisms of extraterrestrial celestial bodies such as the Moon and Mars.

Based on this, how to provide a computational method capable of obtaining a Moho depth distribution over a larger area has become a technical problem urgently requiring a solution in this art.

### SUMMARY

An objective of the present application is to provide a calculation method for a Moho depth of an extraterrestrial celestial body and a related apparatus that enable the acquisition of Moho depth distribution over a larger area, thereby contributing to the understanding of the geological structure, formation process, and evolutionary mechanism of the extraterrestrial celestial body.

To achieve the above objective, the present application provides the following technical solutions.

In a first aspect, the present application provides a calculation method for a Moho depth of an extraterrestrial celestial body, including:
obtaining a seismic event with location information from a target extraterrestrial celestial body, and picking up observed travel time differences T_{obs} of a plurality of seismic phases of seismic body waves relative to a first-arriving P-wave, where the seismic event with location information refers to an event containing seismic source location information monitored using a station along an event-station great circle path;
establishing a plurality of seismological structural models based on the seismic event with location information and the observed travel time differences T_{obs}, where each of the plurality of seismological structural models corresponds to one crustal P-wave velocity value, one crustal S-wave velocity value, one mantle P-wave velocity value, one mantle S-wave velocity value, and one Moho depth value;
calculating a theoretical travel time and a theoretical P-wave first-arrival time for each of the plurality of seismic phases based on each of the plurality of seismological structural models to obtain a theoretical travel time difference T_{cal} of each of the plurality of seismic phases relative to the first-arriving P-wave;
calculating a travel time residual Tᵣₑₛ of each of the plurality of seismological structural models based on the theoretical travel time difference T_{cal} and the observed travel time differences T_{obs}; and
determining an average Moho depth of the event-station great circle path of the target extraterrestrial celestial body based on the travel time residual Tᵣₑₛ of each of the plurality of seismological structural models.

Optionally, the establishing a plurality of seismological structural models based on the seismic event with location information and the observed travel time differences T_{obs} may specifically include:
determining a crustal P-wave velocity range, a crustal S-wave velocity range, a mantle P-wave velocity range, a mantle S-wave velocity range, and a Moho depth range of the target extraterrestrial celestial body based on the seismic event with location information and the observed travel time differences T_{obs};
discretizing the crustal P-wave velocity range, the crustal S-wave velocity range, the mantle P-wave velocity range, the mantle S-wave velocity range, and the Moho depth range to obtain a discretized crustal P-wave velocity, a discretized crustal S-wave velocity, a discretized mantle P-wave velocity, a discretized mantle S-wave velocity, and a discretized Moho depth, respectively; and
establishing the plurality of seismological structural models based on the discretized crustal P-wave velocity, the discretized crustal S-wave velocity, the discretized mantle P-wave velocity, the discretized mantle S-wave velocity, and the discretized Moho depth.

Optionally, the establishing the plurality of seismological structural models based on the discretized crustal P-wave velocity, the discretized crustal S-wave velocity, the discretized mantle P-wave velocity, the discretized mantle S-wave velocity, and the discretized Moho depth may specifically include:
randomly combining parameter values of the discretized crustal P-wave velocity, the discretized crustal S-wave velocity, the discretized mantle P-wave velocity, the discretized mantle S-wave velocity, and the discretized Moho depth to obtain randomly combined sets of parameter values, thereby obtaining the plurality of seismological structural models, where each of the randomly combined sets of parameter values constitutes one of the plurality of seismological structural models and includes one crustal P-wave velocity value, one crustal S-wave velocity value, one mantle P-wave velocity value, one mantle S-wave velocity value, and one Moho depth value.

Optionally, during the discretizing, a velocity increment for the crustal P-wave velocity, the crustal S-wave velocity, the mantle P-wave velocity, and the mantle S-wave velocity is 0.1 km/s, and an increment for the Moho depth is 5 km.

Optionally, a formula for calculating the travel time residual Tᵣₑₛ of each of the plurality of seismological structural models based on the theoretical travel time difference T_{cal} and the observed travel time differences T_{obs} is as follows:

$${T}_{res} = {\vert {T}_{cal} - {T}_{obs} \vert}^{2} .$$

Optionally, the determining an average Moho depth of the event-station great circle path of the target extraterrestrial celestial body based on the travel time residual Tᵣₑₛ of each of the plurality of seismological structural models may specifically include:
normalizing and averaging the travel time residuals Tᵣₑₛ of the plurality of seismological structural models to obtain average values of the normalized travel time residuals Tᵣₑₛ of the plurality of seismological structural models;
selecting average values of the normalized travel time residuals Tᵣₑₛ calculated for the seismological structural models corresponding to a same Moho depth based on the average values of the normalized travel time residuals Tᵣₑₛ of the plurality of seismological structural models; and
selecting a Moho depth corresponding to a minimum value among the average values of the normalized travel time residuals Tᵣₑₛ calculated for the seismological structural models corresponding to the same Moho depth as the average Moho depth of the event-station great circle path of the target extraterrestrial celestial body.

Optionally, the plurality of seismic phases may include PP, SS, PPP, SSS, pP, sP, and sS.

In a second aspect, the present application provides a computer device, including a memory, a processor, and a computer program stored on the memory and runnable on the processor, where the processor is configured to execute the computer program to implement the calculation method for a Moho depth of an extraterrestrial celestial body described above.

In a third aspect, the present application provides a computer-readable storage medium, storing a computer program, where when the computer program is executed by a processor, the calculation method for a Moho depth of an extraterrestrial celestial body described above is implemented.

In a fourth aspect, the present application provides a computer program product, including a computer program, where when the computer program is executed by a processor, the calculation method for a Moho depth of an extraterrestrial celestial body described above is implemented.

According to specific embodiments provided in the present application, the present application has the following technical effects.

The present application provides a calculation method for a Moho depth of an extraterrestrial celestial body and a related apparatus. The average Moho depth of the event-station great circle path is obtained with the relative travel times of the plurality of seismic phases of the seismic body waves. Firstly, the observed travel time differences T_{obs} of the plurality of seismic phases of the seismic body waves relative to the first-arriving P-wave, and then the plurality of seismological structural models are established for calculating the theoretical travel time difference T_{cal} of each seismic phase relative to the first-arriving P-wave. Thus, the travel time residual Tᵣₑₛ of each seismological structural model based on the observed travel time differences T_{obs} and the theoretical travel time difference T_{cal}, and then the average Moho depth of the event-station great circle path can be determined based on the travel time residuals Tᵣₑₛ of the seismological structural models. In view of the problem of the traditional receiver function method (i.e., it can only provide the Moho depth information at the location where the seismometer is deployed, and cannot obtain the Moho depth distribution over a larger area), in the present application, on the basis of the relative travel times of the plurality of seismic phases of the seismic body waves, each set of parameters (one crustal P-wave velocity value, one crustal S-wave velocity value, one mantle P-wave velocity value, one mantle S-wave velocity value, and one Moho depth value) constitutes one seismological structural model such that each seismological structural model corresponds to one Moho depth. Therefore, the Moho depth distribution over a larger area can be obtained, thereby obtaining the more accurate and reliable Moho depth result. This is conducive to understanding the geological structures, formation processes, and evolutionary mechanisms of extraterrestrial celestial bodies.

### BRIEF DESCRIPTION OF THE DRAWINGS

To describe the technical solutions in the embodiments of the present application or in the related art more clearly, the following briefly describes the accompanying drawings required for describing the embodiments or the related art. Apparently, the accompanying drawings in the following description show some embodiments of the present application, and a person of ordinary skill in the art may still derive other accompanying drawings from these accompanying drawings without creative efforts.

FIG. 1 is a diagram showing an environment in which a calculation method for a Moho depth of an extraterrestrial celestial body provided by an embodiment of the present application is employed;

FIG. 2 is a flowchart of a calculation method for a Moho depth of an extraterrestrial celestial body provided by an embodiment of the present application;

FIG. 3 is a schematic diagram of a seismic event with location information, a station and a great circle path for Mars provided by an embodiment of the present application;

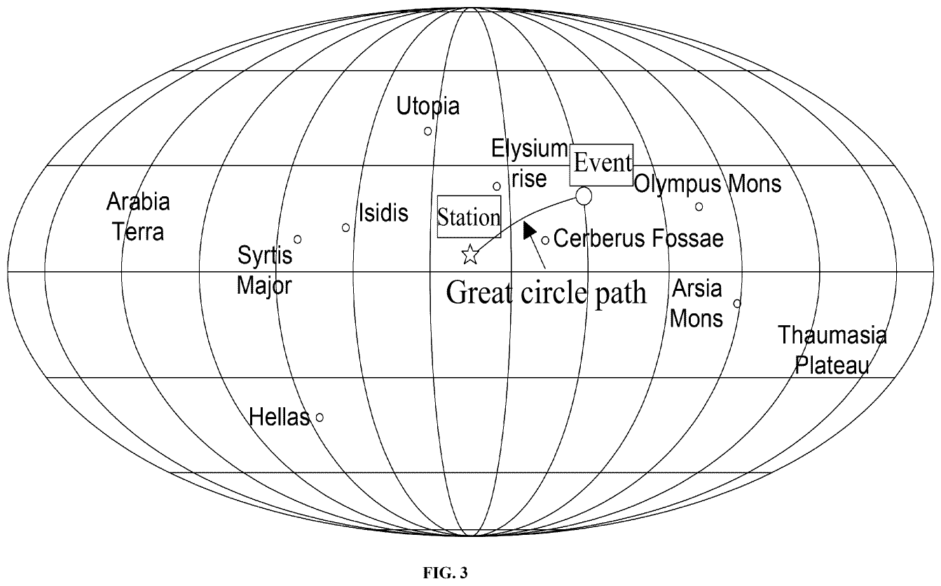

FIG. 4 is a schematic diagram of seismic wave paths of different seismic phases and a location of the Moho provided by an embodiment of the present application;

FIG. 5 is a schematic diagram of an average Moho depth of an event-station great circle path provided by an embodiment of the present application; and

FIG. 6 is a schematic structural diagram of a computer device provided by an embodiment of the present application.

### DETAILED DESCRIPTION OF THE EMBODIMENTS

The technical solutions in the embodiments of the present application are clearly and completely described below with reference to the drawings in the embodiments of the present application. Apparently, the described embodiments are only some rather than all of the embodiments of the present application. All other embodiments derived from the embodiments in the present application by a person of ordinary skill in the art without creative efforts should fall within the protection scope of the present application.

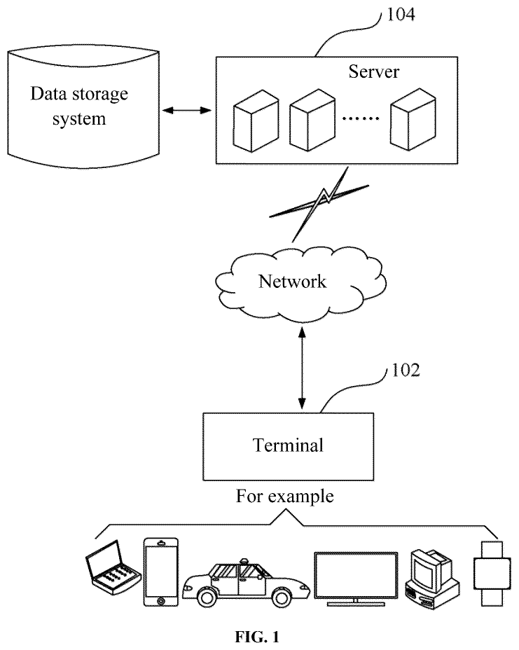

A calculation method for a Moho depth of an extraterrestrial celestial body provided by an embodiment of the present application may be applied to the environment as shown in FIG. 1. A terminal 102 communicates with a server 104 over a network. A data storage system may store data needing to be processed by the server 104. The data storage system may be arranged separately, or integrated with the server 104, or disposed on cloud or other servers. The terminal 102 may send data to be processed to the server 104. After the server 104 receives the data to be processed, for the data to be processed, the server 104 may perform the steps of: obtaining a seismic event with location information from a target extraterrestrial celestial body, and picking up observed travel time differences T_{obs} of a plurality of seismic phases of seismic body waves relative to a first-arriving P-wave; establishing a plurality of seismological structural models; calculating a theoretical travel time and a theoretical P-wave first-arrival time for each seismic phase to obtain a theoretical travel time difference T_{cal} of the seismic phase relative to the first-arriving P-wave; calculating a travel time residual Tᵣₑₛ of each seismological structural model based on the theoretical travel time difference T_{cal} and the observed travel time differences T_{obs}; and determining an average Moho depth of an event-station great circle path of the target extraterrestrial celestial body based on the travel time residual Tᵣₑₛ of each seismological structural model. The server 104 may feed back the obtained average Moho depth of the event-station great circle path to the terminal 102. Furthermore, in some embodiments, the calculation method for a Moho depth of an extraterrestrial celestial body may be implemented by the server 104 or the terminal 102 alone. For example, the Moho depth may be calculated by the terminal 102 directly for the data to be processed. Alternatively, the server 104 obtains the data to be processed from the data storage system and then calculates the Moho depth for the data to be processed.

The terminal 102 may be, but not limited to, various desktop computers, laptop computers, smartphones, tablet computers, Internet-of-Things devices, and portable wearable devices. The Internet-of-Things devices may be smart speakers, smart televisions, smart air conditioners, smart vehicular devices, etc. The portable wearable devices may be smart watches, smart bracelets, headset devices, etc. The server 104 can be implemented by a standalone server or a server cluster made up of a plurality of servers, or may be a cloud server.

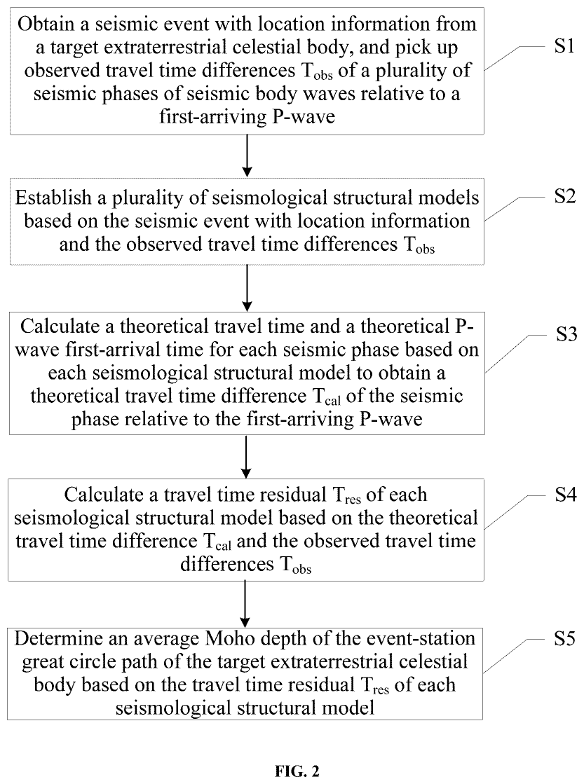

In an exemplary embodiment, as shown in FIG. 2, provided is a calculation method for a Moho depth of an extraterrestrial celestial body, which may be applied to scenarios of calculating Moho depths of extraterrestrial celestial bodies such as Mars and Moon. The method is performed by a computer device, specifically performed separately by a computer device such as a terminal or a server, or performed jointly by a terminal and a server. In an embodiment of the present application, the receiver function vulnerability assessment method is applied to the server 104 in FIG. 1 for example, and may specifically include the following steps.

In step S1, a seismic event with location information is obtained from a target extraterrestrial celestial body, and observed travel time differences T_{obs} of a plurality of seismic phases of seismic body waves relative to a first-arriving P-wave are picked up.

In this embodiment, the target extraterrestrial celestial body refers to a celestial body object of which the Moho depth is to be calculated, such as Mars and Moon. The seismic event with location information refers to seismic source location information of an event detected using a device such as a seismometer of a station. A spatial path from the event to the station on the extraterrestrial celestial body such as Mars and Moon is an event-station great circle path. Therefore, the seismic event with location information refers to an event containing seismic source location information monitored using the station in the event-station great circle path.

A seismic phase refers to a group of seismic waves with different properties or different propagation paths shown on a seismogram. Various seismic phases possess their own features in terms of arrival time, waveform, amplitude, period, and particle motion pattern. The features of a seismic phase depend on the properties of a seismic source, a propagation medium, and a receiving instrument. Since these wave groups each have a certain duration, the waveforms of different phases overlap and interfere with each other, resulting in a complex pattern on the seismogram. Under normal circumstances, only the onset of a seismic phase can be identified. One of the tasks of seismology is to analyze and interpret the causes and physical significance of various seismic phases, and to utilize the features of various seismic phases to determine fundamental earthquake parameters, investigate the mechanical properties of a seismic source, and explore the internal structure of the Earth. When a seismic body wave reaches the surface of an extraterrestrial celestial body, it may undergo one or more reflections. If the nature of the wave remains unchanged upon reflection, the seismic phases after reflection may be denoted as PP, PPP, SS, SSS, and the like, respectively. In the case of a deep seismic source, the seismic body waves emitted from the seismic source may first be reflected at the surface near the epicenter before arriving at the observation point of the station, forming another seismic phase known as a depth phase. Lowercase letters are used to represent the wave paths before reflection near the epicenter, such as pP, sP, and sPS. The arrival time differences of pP and sP from P and S are highly sensitive to changes in seismic source depth. Therefore, these seismic phases serve as the primary basis for determining the source depths of deep earthquakes. In this embodiment, the plurality of seismic phases include PP, SS, PPP, SSS, pP, sP, sS, etc.

In step S2, a plurality of seismological structural models are established based on the seismic event with location information and the observed travel time differences T_{obs}. Each seismological structural model corresponds to one crustal P-wave velocity value, one crustal S-wave velocity value, one mantle P-wave velocity value, one mantle S-wave velocity value, and one Moho depth value.

In this embodiment, step S2 in which the plurality of seismological structural models are established based on the seismic event with location information and the observed travel time differences T_{obs} specifically includes the following steps.

In step S21, a crustal P-wave velocity range, a crustal S-wave velocity range, a mantle P-wave velocity range, a mantle S-wave velocity range, and a Moho depth range of the target extraterrestrial celestial body are determined based on the seismic event with location information and the observed travel time differences T_{obs}.

In step S22, the crustal P-wave velocity range, the crustal S-wave velocity range, the mantle P-wave velocity range, the mantle S-wave velocity range, and the Moho depth range are discretized to obtain a discretized crustal P-wave velocity, a discretized crustal S-wave velocity, a discretized mantle P-wave velocity, a discretized mantle S-wave velocity, and a discretized Moho depth, respectively.

In this embodiment, during the discretizing, a velocity increment for the crustal P-wave velocity, the crustal S-wave velocity, the mantle P-wave velocity, and the mantle S-wave velocity is 0.1 km/s, and an increment for the Moho depth is 5 km. The specific values of the increments may be set according to actual circumstances.

In step S23, the plurality of seismological structural models are established based on the discretized crustal P-wave velocity, the discretized crustal S-wave velocity, the discretized mantle P-wave velocity, the discretized mantle S-wave velocity, and the discretized Moho depth.

In this embodiment, step S23 in which the plurality of seismological structural models are established based on the discretized crustal P-wave velocity, the discretized crustal S-wave velocity, the discretized mantle P-wave velocity, the discretized mantle S-wave velocity, and the discretized Moho depth specifically includes the following steps.

Parameter values of the discretized crustal P-wave velocity, the discretized crustal S-wave velocity, the discretized mantle P-wave velocity, the discretized mantle S-wave velocity, and the discretized Moho depth are randomly combined to obtain randomly combined sets of parameter values, thereby obtaining the plurality of seismological structural models, where each of the randomly combined sets of parameter values constitutes one of the plurality of seismological structural models and includes one crustal P-wave velocity value, one crustal S-wave velocity value, one mantle P-wave velocity value, one mantle S-wave velocity value, and one Moho depth value.

In step S3, a theoretical travel time and a theoretical P-wave first-arrival time for each seismic phase are calculated based on each seismological structural model to obtain a theoretical travel time difference T_{cal} of the seismic phase relative to the first-arriving P-wave.

In step S4, a travel time residual Tᵣₑₛ of each seismological structural model is calculated based on the theoretical travel time difference T_{cal} and the observed travel time differences T_{obs}.

In this embodiment, the travel time residual Tᵣₑₛ of each seismological structural model is calculated using the following formula:

$${T}_{res} = {\vert {T}_{cal} - {T}_{obs} \vert}^{2} .$$

In step S5, an average Moho depth of the event-station great circle path of the target extraterrestrial celestial body is determined based on the travel time residual Tᵣₑₛ of each seismological structural model.

In this embodiment, step S5 in which the average Moho depth of the event-station great circle path of the target extraterrestrial celestial body is determined based on the travel time residual Tᵣₑₛ of each seismological structural model specifically includes the following steps.

In step S51, the travel time residuals Tᵣₑₛ of the plurality of seismological structural models are normalized and averaged to obtain average values of the normalized travel time residuals Tᵣₑₛ of the plurality of seismological structural models.

In step S52, average values of the normalized travel time residuals Tᵣₑₛ calculated for the seismological structural models corresponding to a same Moho depth are selected based on the average values of the normalized travel time residuals Tᵣₑₛ of the plurality of seismological structural models.

In step S53, a Moho depth corresponding to a minimum value (i.e., the minimum average value of the normalized travel time residuals Tᵣₑₛ) among the average values of the normalized travel time residuals Tᵣₑₛ calculated for the seismological structural models corresponding to the same Moho depth is selected as the average Moho depth of the event-station great circle path of the target extraterrestrial celestial body.

To make the technical solution of this embodiment clearer, the complete implementation process of the technical solution of this embodiment will be described in detail below by way of example. The specific implementation steps are as follows.

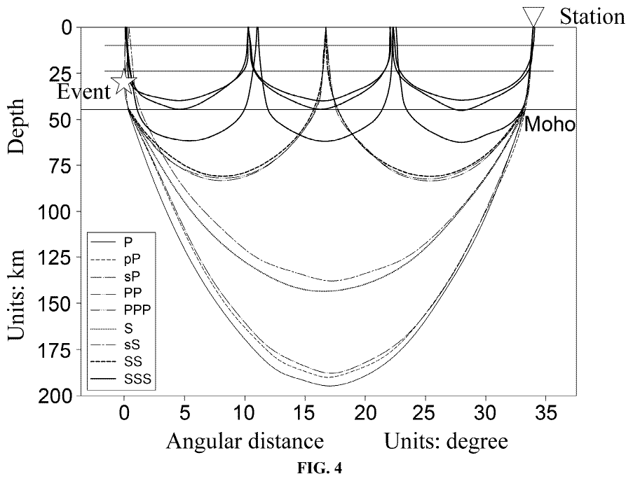

In step 1, a seismic event with location information is obtained, and travel time differences of a plurality of seismic phases of seismic body waves relative to a first-arriving P-wave are picked up. These seismic phases include, but are not limited to, PP, SS, PPP, SSS, pP, sP, sS, and the like, as shown in FIG. 4. The travel time difference refers to an observed time difference, denoted as an observed travel time difference T_{obs}.

In step 2, a P-wave velocity range and an S-wave velocity range for the crust and the mantle and a Moho depth range are determined.

In step 3, the P-wave velocities and the S-wave velocities in the crust and the mantle and the Moho depth in step 2 are discretized at certain increments. That is, the value ranges of the above parameters are spaced apart according to preset increment values. For example, the velocity increment is 0.1 km/s, and the increment for the Moho depth is 5 km.

In step 4, each combination of the parameter values of the crustal P-wave velocity, the crustal S-wave velocity, the mantle P-wave velocity, the mantle S-wave velocity, and the Moho depth in step 3 constitutes one seismological structural model. That is, one seismological structural model corresponds to one crustal P-wave velocity, one crustal S-wave velocity, one mantle P-wave velocity, one mantle S-wave velocity, and one Moho depth. Thus, tens of thousands of seismological structural models are generated.

In step 5, a theoretical travel time and a theoretical P-wave first-arrival time for each seismic phase in step 1 are calculated based on each seismological structural model generated in step 4 to obtain its travel time difference relative to the first-arriving P-wave, denoted as a theoretical travel time difference T_{cal}.

In step 6, a travel time residual Tᵣₑₛ=|T_{cal}−T_{obs}|² of each seismological structural model is calculated based on the observed travel time differences T_{obs} obtained in step 1 and the theoretical travel time difference T_{cal} obtained in step 5.

In step 7, since each seismological structural model corresponds to one Moho depth, the travel time residuals Tᵣₑₛ of the seismological structural models obtained in step 6 are normalized and averaged, and average values of the normalized travel time residuals Tᵣₑₛ calculated for the seismological structural models corresponding to a same Moho depth are selected.

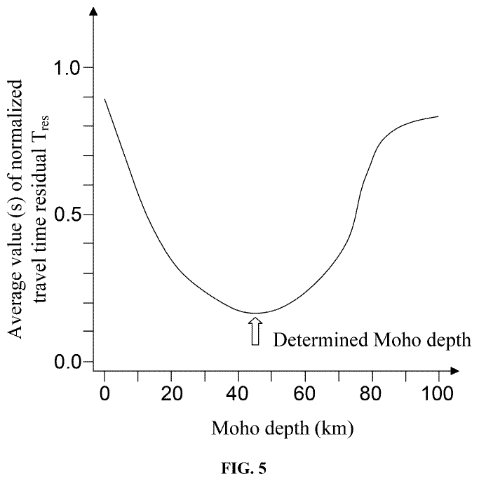

In step 8, the Moho depth corresponding to the minimum value among the average values of the travel time residuals Tᵣₑₛ in step 7 is selected as the average Moho depth of the event-station great circle path. As shown in FIG. 5, the horizontal axis in FIG. 5 represents the Moho depth and the vertical axis represents the average value of the normalized travel time residuals Tᵣₑₛ. The lowest point of the curve in FIG. 5 indicates that the Moho depth corresponding to the minimum average value of the normalized travel time residuals Tᵣₑₛ is the finally determined Moho depth result.

In this embodiment, after the travel time residuals Tᵣₑₛ of the seismological structural models are obtained, the average values of the normalized travel time residuals Tᵣₑₛ may be calculated through the normalizing and averaging process. Accordingly, a changing curve of the average value of the normalized travel time residual Tᵣₑₛ vs the Moho depth as shown in FIG. 5 may be generated. The Moho depth corresponding to the minimum value among the average values of the normalized travel time residuals Tᵣₑₛ is then determined as the final average Moho depth of the event-station great circle path. The Moho depth result can be obtained accurately and reliably.

The present application provides a calculation method for a Moho depth of an extraterrestrial celestial body and a related apparatus. The average Moho depth of the event-station great circle path is obtained with the relative travel times of the plurality of seismic phases of the seismic body waves. Firstly, the observed travel time differences T_{obs} of the plurality of seismic phases of the seismic body waves relative to the first-arriving P-wave, and then the plurality of seismological structural models are established for calculating the theoretical travel time difference T_{cal} of each seismic phase relative to the first-arriving P-wave. Thus, the travel time residual Tᵣₑₛ of each seismological structural model based on the theoretical travel time difference T_{cal} and the observed travel time differences T_{obs}, and then the average Moho depth of the event-station great circle path can be determined based on the travel time residuals Tᵣₑₛ of the seismological structural models. In view of the problem of the traditional receiver function method (i.e., it can only provide the Moho depth information at the location where the seismometer is deployed, and cannot obtain the Moho depth distribution over a larger area), in the present application, on the basis of the relative travel times of the plurality of seismic phases of the seismic body waves, each set of parameters (one crustal P-wave velocity value, one crustal S-wave velocity value, one mantle P-wave velocity value, one mantle S-wave velocity value, and one Moho depth value) constitutes one seismological structural model such that each seismological structural model corresponds to one Moho depth. Therefore, the Moho depth distribution over a larger area can be obtained, thereby obtaining the more accurate and reliable Moho depth result. This is conducive to understanding the geological structures, formation processes, and evolutionary mechanisms of extraterrestrial celestial bodies.

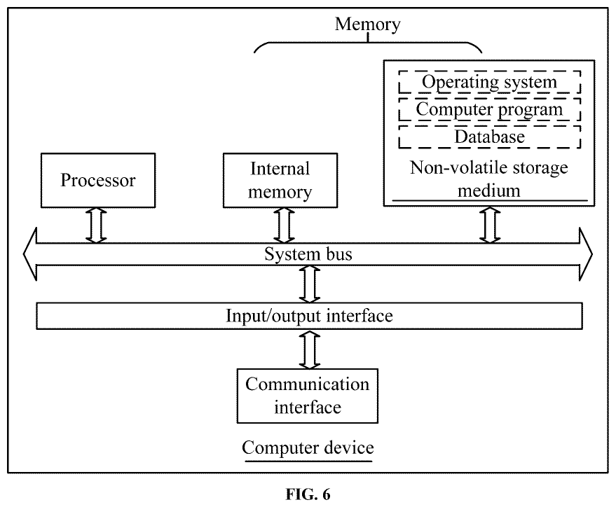

In an exemplary embodiment, a computer device is provided. The computer device may be a server or a terminal, and an internal structure thereof may be as shown in FIG. 6. The computer device includes a processor, a memory, an input/output interface (I/O), and a communication interface. The processor, the memory, and the input/output interface are connected via a system bus, and the communication interface is connected to the system bus via the input/output interface. The processor of the computer device is configured to provide computing and control capabilities. The memory of the computer device includes a nonvolatile storage medium and an internal memory. The non-volatile storage medium stores an operating system, a computer program, and a database. The internal memory provides an environment for operation of the operating system and the computer program in the nonvolatile storage medium. The database of the computer device is configured to store data for calculating a Moho depth of an extraterrestrial celestial body, i.e., the data to be processed. The input/output interface of the computer device is configured to exchange information between the processor and an external device. The communication interface of the computer device is configured to communicate with an external terminal through a network. When the computer program is executed by the processor, a calculation method for a Moho depth of an extraterrestrial celestial body is implemented.

Those skilled in the art may understand that the structure shown in FIG. 6 is only a block diagram of a part of the structure related to the solutions of the present application and does not constitute a limitation on a computer device to which the solutions of the present application are applied. Specifically, the computer device may include more or less components than those shown in the figure, or combine some components, or have different component arrangements.

In an exemplary embodiment, further provided is a computer device, including a memory and a processor, where the memory stores a computer program, and the computer program is executed by the processor to implement the calculation method for a Moho depth of an extraterrestrial celestial body described above.

In an exemplary embodiment, provided is a computer-readable storage medium, storing a computer program, where when the computer program is executed by a processor, the calculation method for a Moho depth of an extraterrestrial celestial body described above is implemented.

In an exemplary embodiment, provided is a computer program product, including a computer program, where when the computer program is executed by a processor, the calculation method for a Moho depth of an extraterrestrial celestial body described above is implemented.

Those of ordinary skill in the art may understand that all or some of the procedures in the methods of the above embodiments may be implemented by a computer program instructing related hardware. The computer program may be stored in a nonvolatile computer-readable storage medium. When the computer program is executed, the procedures in the embodiments of the above methods may be performed. Any reference to a memory, a database, or other media used in the embodiments of the present application may include a non-volatile and/or volatile memory. The nonvolatile memory may include a read-only memory (ROM), a magnetic tape, a floppy disk, a flash memory, an optical memory, a high-density embedded nonvolatile memory, a resistive random access memory (ReRAM), a magnetoresistive random access memory (MRAM), a ferroelectric random access memory (FRAM), a phase change memory (PCM), a graphene memory, etc. The volatile memory may include a random access memory (RAM) or an external cache memory. As an illustration rather than a limitation, the RAM may be in various forms, such as a static random access memory (SRAM) or a dynamic random access memory (DRAM).

The technical features of the foregoing embodiments can be combined arbitrarily. For brevity of description, not all possible combinations of the technical features of the foregoing embodiments are described. However, the combinations of these technical features should be construed as falling within the scope described in this specification as long as there is no contradiction between the combinations.

Several examples are used herein for illustration of the principles and implementations of the present application. The description of the foregoing examples is used to help illustrate the method of the present application and the core principles thereof. In addition, those of ordinary skill in the art can make various modifications in terms of specific implementations and scope of application in accordance with the teachings of the present application. In conclusion, the content of the present specification shall not be construed as a limitation to the present application.

What is claimed is:

1. A calculation method for a Mohorovičić discontinuity (Moho) depth of an extraterrestrial celestial body, comprising:
obtaining a seismic event with location information from a target extraterrestrial celestial body, and picking up observed travel time differences T_{obs} of a plurality of seismic phases of seismic body waves relative to a first-arriving P-wave, wherein the seismic event with location information refers to an event containing seismic source location information monitored using a station along an event-station great circle path;
establishing a plurality of seismological structural models based on the seismic event with location information and the observed travel time differences T_{obs}, wherein each of the plurality of seismological structural models corresponds to one crustal P-wave velocity value, one crustal S-wave velocity value, one mantle P-wave velocity value, one mantle S-wave velocity value, and one Moho depth value;
calculating a theoretical travel time and a theoretical P-wave first-arrival time for each of the plurality of seismic phases based on each of the plurality of seismological structural models to obtain a theoretical travel time difference T_{cal} of each of the plurality of seismic phases relative to the first-arriving P-wave;
calculating a travel time residual Tᵣₑₛ of each of the plurality of seismological structural models based on the theoretical travel time difference T_{cal} and the observed travel time differences T_{obs}; and
determining an average Moho depth of the event-station great circle path of the target extraterrestrial celestial body based on the travel time residual Tᵣₑₛ of each of the plurality of seismological structural models.

2. The calculation method for a Moho depth of an extraterrestrial celestial body according to claim 1, wherein the establishing a plurality of seismological structural models based on the seismic event with location information and the observed travel time differences T_{obs} comprises:
determining a crustal P-wave velocity range, a crustal S-wave velocity range, a mantle P-wave velocity range, a mantle S-wave velocity range, and a Moho depth range of the target extraterrestrial celestial body based on the seismic event with location information and the observed travel time differences T_{obs};
discretizing the crustal P-wave velocity range, the crustal S-wave velocity range, the mantle P-wave velocity range, the mantle S-wave velocity range, and the Moho depth range to obtain a discretized crustal P-wave velocity, a discretized crustal S-wave velocity, a discretized mantle P-wave velocity, a discretized mantle S-wave velocity, and a discretized Moho depth, respectively; and
establishing the plurality of seismological structural models based on the discretized crustal P-wave velocity, the discretized crustal S-wave velocity, the discretized mantle P-wave velocity, the discretized mantle S-wave velocity, and the discretized Moho depth.

3. The calculation method for a Moho depth of an extraterrestrial celestial body according to claim 2, wherein the establishing the plurality of seismological structural models based on the discretized crustal P-wave velocity, the discretized crustal S-wave velocity, the discretized mantle P-wave velocity, the discretized mantle S-wave velocity, and the discretized Moho depth comprises:
randomly combining parameter values of the discretized crustal P-wave velocity, the discretized crustal S-wave velocity, the discretized mantle P-wave velocity, the discretized mantle S-wave velocity, and the discretized Moho depth to obtain randomly combined sets of parameter values, thereby obtaining the plurality of seismological structural models, wherein each of the randomly combined sets of parameter values constitutes one of the plurality of seismological structural models and comprises one crustal P-wave velocity value, one crustal S-wave velocity value, one mantle P-wave velocity value, one mantle S-wave velocity value, and one Moho depth value.

4. The calculation method for a Moho depth of an extraterrestrial celestial body according to claim 2, wherein during the discretizing, a velocity increment for the crustal P-wave velocity, the crustal S-wave velocity, the mantle P-wave velocity, and the mantle S-wave velocity is 0.1 km/s, and an increment for the Moho depth is 5 km.

5. The calculation method for a Moho depth of an extraterrestrial celestial body according to claim 1, wherein a formula for calculating the travel time residual Tᵣₑₛ of each of the plurality of seismological structural models based on the theoretical travel time difference T_{cal} and the observed travel time differences T_{obs} is as follows:
$${T}_{res} = {\vert {T}_{cal} - {T}_{obs} \vert}^{2} .$$

6. The calculation method for a Moho depth of an extraterrestrial celestial body according to claim 1, wherein the determining an average Moho depth of the event-station great circle path of the target extraterrestrial celestial body based on the travel time residual Tᵣₑₛ of each of the plurality of seismological structural models comprises:
normalizing and averaging the travel time residuals Tᵣₑₛ of the plurality of seismological structural models to obtain average values of the normalized travel time residuals Tᵣₑₛ of the plurality of seismological structural models;
selecting average values of the normalized travel time residuals Tᵣₑₛ calculated for the seismological structural models corresponding to a same Moho depth based on the average values of the normalized travel time residuals Tᵣₑₛ of the plurality of seismological structural models; and
selecting a Moho depth corresponding to a minimum value among the average values of the normalized travel time residuals Tᵣₑₛ calculated for the seismological structural models corresponding to the same Moho depth as the average Moho depth of the event-station great circle path of the target extraterrestrial celestial body.

7. The calculation method for a Moho depth of an extraterrestrial celestial body according to claim 1, wherein the plurality of seismic phases comprise PP, SS, PPP, SSS, pP, sP, and sS.

8. A computer device, comprising: a memory, a processor, and a computer program stored on the memory and runnable on the processor, wherein the processor is configured to execute the computer program to implement the calculation method for a Moho depth of an extraterrestrial celestial body according to claim 1.

9. A non-transitory computer-readable storage medium, storing a computer program, wherein when the computer program is executed by a processor, the calculation method for a Moho depth of an extraterrestrial celestial body according to claim 1 is implemented.

10. The computer device according to claim 8, wherein the establishing a plurality of seismological structural models based on the seismic event with location information and the observed travel time differences T_{obs} comprises:
determining a crustal P-wave velocity range, a crustal S-wave velocity range, a mantle P-wave velocity range, a mantle S-wave velocity range, and a Moho depth range of the target extraterrestrial celestial body based on the seismic event with location information and the observed travel time differences T_{obs};
discretizing the crustal P-wave velocity range, the crustal S-wave velocity range, the mantle P-wave velocity range, the mantle S-wave velocity range, and the Moho depth range to obtain a discretized crustal P-wave velocity, a discretized crustal S-wave velocity, a discretized mantle P-wave velocity, a discretized mantle S-wave velocity, and a discretized Moho depth, respectively; and
establishing the plurality of seismological structural models based on the discretized crustal P-wave velocity, the discretized crustal S-wave velocity, the discretized mantle P-wave velocity, the discretized mantle S-wave velocity, and the discretized Moho depth.

11. The computer device according to claim 10, wherein the establishing the plurality of seismological structural models based on the discretized crustal P-wave velocity, the discretized crustal S-wave velocity, the discretized mantle P-wave velocity, the discretized mantle S-wave velocity, and the discretized Moho depth comprises:
randomly combining parameter values of the discretized crustal P-wave velocity, the discretized crustal S-wave velocity, the discretized mantle P-wave velocity, the discretized mantle S-wave velocity, and the discretized Moho depth to obtain randomly combined sets of parameter values, thereby obtaining the plurality of seismological structural models, wherein each of the randomly combined sets of parameter values constitutes one of the plurality of seismological structural models and comprises one crustal P-wave velocity value, one crustal S-wave velocity value, one mantle P-wave velocity value, one mantle S-wave velocity value, and one Moho depth value.

12. The computer device according to claim 10, wherein during the discretizing, a velocity increment for the crustal P-wave velocity, the crustal S-wave velocity, the mantle P-wave velocity, and the mantle S-wave velocity is 0.1 km/s, and an increment for the Moho depth is 5 km.

13. The computer device according to claim 8, wherein a formula for calculating the travel time residual Tᵣₑₛ of each of the plurality of seismological structural models based on the theoretical travel time difference T_{cal} and the observed travel time differences T_{obs} is as follows:
$${T}_{res} = {\vert {T}_{cal} - {T}_{obs} \vert}^{2} .$$

14. The computer device according to claim 8, wherein the determining an average Moho depth of the event-station great circle path of the target extraterrestrial celestial body based on the travel time residual Tᵣₑₛ of each of the plurality of seismological structural models comprises:
normalizing and averaging the travel time residuals Tᵣₑₛ of the plurality of seismological structural models to obtain average values of the normalized travel time residuals Tᵣₑₛ of the plurality of seismological structural models;
selecting average values of the normalized travel time residuals Tᵣₑₛ calculated for the seismological structural models corresponding to a same Moho depth based on the average values of the normalized travel time residuals Tᵣₑₛ of the plurality of seismological structural models; and
selecting a Moho depth corresponding to a minimum value among the average values of the normalized travel time residuals Tᵣₑₛ calculated for the seismological structural models corresponding to the same Moho depth as the average Moho depth of the event-station great circle path of the target extraterrestrial celestial body.

15. The computer device according to claim 8, wherein the plurality of seismic phases comprise PP, SS, PPP, SSS, pP, sP, and sS.

16. The non-transitory computer-readable storage medium according to claim 9, wherein the establishing a plurality of seismological structural models based on the seismic event with location information and the observed travel time differences T_{obs} comprises:
determining a crustal P-wave velocity range, a crustal S-wave velocity range, a mantle P-wave velocity range, a mantle S-wave velocity range, and a Moho depth range of the target extraterrestrial celestial body based on the seismic event with location information and the observed travel time differences T_{obs};
discretizing the crustal P-wave velocity range, the crustal S-wave velocity range, the mantle P-wave velocity range, the mantle S-wave velocity range, and the Moho depth range to obtain a discretized crustal P-wave velocity, a discretized crustal S-wave velocity, a discretized mantle P-wave velocity, a discretized mantle S-wave velocity, and a discretized Moho depth, respectively; and
establishing the plurality of seismological structural models based on the discretized crustal P-wave velocity, the discretized crustal S-wave velocity, the discretized mantle P-wave velocity, the discretized mantle S-wave velocity, and the discretized Moho depth.

17. The non-transitory computer-readable storage medium according to claim 16, wherein the establishing the plurality of seismological structural models based on the discretized crustal P-wave velocity, the discretized crustal S-wave velocity, the discretized mantle P-wave velocity, the discretized mantle S-wave velocity, and the discretized Moho depth comprises:
randomly combining parameter values of the discretized crustal P-wave velocity, the discretized crustal S-wave velocity, the discretized mantle P-wave velocity, the discretized mantle S-wave velocity, and the discretized Moho depth to obtain randomly combined sets of parameter values, thereby obtaining the plurality of seismological structural models, wherein each of the randomly combined sets of parameter values constitutes one of the plurality of seismological structural models and comprises one crustal P-wave velocity value, one crustal S-wave velocity value, one mantle P-wave velocity value, one mantle S-wave velocity value, and one Moho depth value.

18. The non-transitory computer-readable storage medium according to claim 16, wherein during the discretizing, a velocity increment for the crustal P-wave velocity, the crustal S-wave velocity, the mantle P-wave velocity, and the mantle S-wave velocity is 0.1 km/s, and an increment for the Moho depth is 5 km.

19. The non-transitory computer-readable storage medium according to claim 9, wherein a formula for calculating the travel time residual Tᵣₑₛ of each of the plurality of seismological structural models based on the theoretical travel time difference T_{cal} and the observed travel time differences T_{obs} is as follows:
$${T}_{res} = {\vert {T}_{cal} - {T}_{obs} \vert}^{2} .$$

20. The non-transitory computer-readable storage medium according to claim 9, wherein the determining an average Moho depth of the event-station great circle path of the target extraterrestrial celestial body based on the travel time residual Tᵣₑₛ of each of the plurality of seismological structural models comprises:
normalizing and averaging the travel time residuals Tᵣₑₛ of the plurality of seismological structural models to obtain average values of the normalized travel time residuals Tᵣₑₛ of the plurality of seismological structural models;
selecting average values of the normalized travel time residuals Tᵣₑₛ calculated for the seismological structural models corresponding to a same Moho depth based on the average values of the normalized travel time residuals Tᵣₑₛ of the plurality of seismological structural models; and
selecting a Moho depth corresponding to a minimum value among the average values of the normalized travel time residuals Tᵣₑₛ calculated for the seismological structural models corresponding to the same Moho depth as the average Moho depth of the event-station great circle path of the target extraterrestrial celestial body.
